(19) United States
(12) Patent Application Publication
(10) Pub. No.: US 2004/0061524 A1
(43) Pub. Date: Apr. 1, 2004

(54) Digital electronic circuit for translating high voltage levels to low voltage levels

(75) Inventors: Manoj Kumar, New Delhi (IN); Sunil Chandra Kasanyal, Pithoragarh (IN)

Correspondence Address: CHRISTOPHER F. REGAN, Allen, Dyer, Doppelt, Milbrath & Gilchrist, P.A., Suite 1401, 255 S. Orange Ave., P.O. Box 3791, Orlando, FL, 32802, US

(73) Assignee: STMicroelectronics Pvt. Ltd., Noida (IN)

(21) Appl. No.: 10/611,322

(22) Filed: Jul. 1, 2003

Related U.S. Application Data
(63) Continuation-in-part of application No. 10/460,044, filed on Jun. 12, 2003.

(30) Foreign Application Priority Data
Jun. 13, 2002 (IN) 635/DEL/2002
Jul. 1, 2003 (IN) 706/DEL/2002

(51) Int. Cl. H03K 19/0175

(52) U.S. Cl. 326/81

(57) ABSTRACT

A voltage level translator for digital logic circuits provides high level to low level voltage translation with equal rise and fall delays. The voltage level translator may include an input high voltage logic inverter (operating at the high voltage level) and connected to an output low voltage logic inverter operating at the low voltage level via a voltage reduction circuit. A related method for providing high level to low voltage translation may include providing an input inverter operating at the high voltage level and an output inverter operating at the low voltage level. Furthermore, the output of the high voltage inverter may be coupled to the input of the low voltage inverter after reducing the output voltage of the high voltage inverter to the required level.

### CROSS-REFERENCE TO RELATED APPLICATIONS

This application is a continuation-in-part of co-pending U.S. patent application Ser. No. 10/460,044, filed Jun. 12, 2003, which is hereby incorporated herein in its entirety by reference.

### FIELD OF THE INVENTION

The present invention relates to the field of digital electronic circuits and, more particularly, to voltage level translators for translating high voltage levels to low voltage levels in digital integrated circuits.

### BACKGROUND OF THE INVENTION

Many modern digital electronic integrated circuits are designed with multiple sections. Some of these sections may operate at different operating voltages based on functional requirements, etc. These different sections interface with one another using voltage translators for providing signal level compatibility. Yet, the ever-decreasing size of integrated circuit chips has necessitated a reduction in operating voltages to avoid latch-up and other operational problems such as electro-magnetic interference (EMI), etc. As a result, the spacing between the conductors internal to the device have correspondingly decreased.

The use of lower operating voltages also reduces power consumption as well as the amount of heat generated from power dissipation, which can be particularly acute for relatively small device sizes. At the same time, functional requirements for interfacing with other devices typically require signal levels to be at significantly higher voltage levels, have minimum rise and fall times, and low average and peak power dissipation.

Referring to FIG. 1, a typical voltage translator 1 in accordance with the prior art for translating a high voltage input level to a lower voltage output is illustratively shown. The circuit includes two cascaded inverters. The pull-down NMOS transistors NH₁, NH₂ of both inverters are connected to a common ground. The pull-up transistor PH₁ of the input inverter is a high threshold voltage PMOS transistor connected to the higher voltage level V_{DD}_{_{—}}_{HIGH}, and the pull-up transistor PH₂ of the output inverter is connected to the lower voltage level V_{DD}_{_{—}}_{LOW}.

The above-described architecture does not provide equal delays and transition times for rising and falling edges. This is because the PMOS transistor of the output inverter requires the voltage at its gate to drop from V_{DD}_{_{—}}_{HIGH} to (V_{DD}_{_{—}}_{LOW}−V_{T}_{_{—}}_{LOW}). Yet, the NMOS transistor requires its input voltage to rise from 0 to only V_{T}_{_{—}}_{LOW}.

Simulation results for a 3.3V to 1.2V translation using the voltage translator of FIG. 1 are shown in FIG. 2. As may be seen, the rise and fall delays and transition times are unequal. Similarly, the simulation results for a 2.5V to 1.2V translation using the voltage translator of FIG. 1 are shown in FIG. 3. Once again, the rise and fall delays and transition times may be observed to be unequal.

U.S. Pat. No. 5,422,523 provides an example of a device for translating low voltages to high voltages. Even so, this method is generally unsuitable for converting from high voltages to low voltages.

Furthermore, U.S. Pat. No. 6,236,256 discloses a device for translating high voltages to low voltages. As shown in FIG. 4 thereof, the '256 patent describes a converter including an input sampler for sampling an input signal, a storage node for temporarily storing the sampled value, and precharge circuitry for precharging and discharging internal storage node capacitances. A latch is also included for retaining the sensed logic level, and an output low voltage inverter provides the output signal.

The invention described in the '256 patent does not provide equal rise and fall times for the output signal. In fact, the rise and fall times are likely to be significantly different. This is because the high-to-low transition of the output depends on the resistance of the SAMPLE switch and input signal rise-time, while the low-to-high transition depends only on the PRECHARGE value. This method is also relatively complex and expensive to implement.

### SUMMARY OF THE INVENTION

An object of the invention is to provide a device and method for providing voltage translation for signals from a circuit operating at a higher voltage level to a circuit operating at a lower voltage level.

Another object of the invention is to provide high-to-low voltage translation in a device having a relatively small device size.

A further object of the invention is to provide high-to-low voltage translation with equal rise and fall delays and equal rise and fall transition times.

Yet another object of the invention is to provide a high-to-low voltage translator with reduced propagation delay.

Another object of the invention is to provide a high-to-low voltage translator with reduced power dissipation.

These and other objects, features, and advantages of the invention are provided by a digital electronic circuit for providing high level to low level voltage translation with equal rise and fall delays and equal rise and fall transition times. In particular, the electronic circuit may include an input high voltage logic inverter operating at the high level voltage. The input high voltage logic inverter may be connected to an output low voltage logic inverter operating at the low voltage level through a voltage degradation circuit.

The voltage degradation circuit may include a plurality of series-connected transistors each biased to provide a fixed voltage drop. The voltage degradation circuit may provide a voltage that is greater than one threshold voltage below the low voltage level in the high state. This advantageously reduces output leakage current as well as the possibility of “crowbar” conduction. Further, the voltage degradation circuit may also provide a voltage that does not exceed a specified upper voltage rating of the low voltage transistors to reduce the possibility of transistor breakdown. An additional transistor may also be connected to feedback the output of the low level inverter to its input to further reduce output leakage current and the possibility of crowbar conduction.

Additionally, the voltage degraduation circuit may include a low voltage transistor having a common terminal connected to the low voltage supply, and an output terminal connected to the output terminal of a second transistor. The second transistor may have a control terminal connected to the input of the voltage translation circuit, and a common terminal providing the complementary output from the voltage translation circuit. The two complementary outputs may drive the control terminals of the two transistors in the output low voltage inverter.

A method aspect of the invention is for providing high level to low-level voltage translation with equal rise and fall delays and equal rise and fall transition times. More particularly, the method may include providing an input inverter operating at the high voltage level and an output inverter operating at the low voltage level. Further, the output of the high voltage inverter may be coupled to the input of the low voltage inverter after reducing the output voltage of the high voltage inverter to the required level.

### BRIEF DESCRIPTION OF THE DRAWINGS

FIG. 1 is a schematic circuit diagram of a voltage converter in accordance with the prior art.

FIG. 2 is a simulated timing diagram of the prior art voltage converter of FIG. 1 for the case where V_{DD}_{_{—}}_{HIGH}=3.3V and V_{DD}_{_{—}}_{LOW}=1.2V (i.e., a voltage difference of 2.1V).

FIG. 3 is a simulated timing diagram of the prior art voltage converter of FIG. 1 for the case where V_{DD}_{_{—}}_{HIGH}=2.5V and V_{DD}_{_{—}}_{LOW}=1.2V (i.e., a voltage difference of 1.3V).

FIG. 4 is a schematic circuit diagram of a first embodiment of the voltage converter in accordance with the present invention.

FIG. 5 is a simulated timing diagram for the voltage converter of FIG. 4 where V_{DD}_{_{—}}_{HIGH}=3.3V and V_{DD}_{_{—}}_{LOW}=1.2V (i.e., a voltage difference 2.1V).

FIG. 6 is a schematic circuit diagram of a second embodiment of the voltage converter in accordance with the present invention.

FIG. 7 is a simulated timing diagram for the voltage converter of FIG. 6 where V_{DD}_{_{—}}_{HIGH}=2.5V and V_{DD}_{_{—}}_{LOW}=1.2V (i.e., a voltage difference 1.3 V).

FIG. 8 is a graph comparing the simulated timing diagrams of a prior art voltage converter and a voltage converter in accordance with the present invention where V_{DD}_{_{—}}_{HIGH}=3.3V and V_{DD}_{_{—}}_{LOW}=1.2V.

FIG. 9 is a graph comparing the simulated timing diagrams of a prior art voltage converter and a voltage converter in accordance with the present invention where V_{DD}_{_{—}}_{HIGH}=2.5V and V_{DD}_{_{—}}_{LOW}=1.2V.

FIG. 10 is a schematic circuit diagram of a third embodiment of the voltage converter in accordance with the present invention.

FIG. 11 is a schematic circuit diagram of a fourth embodiment of the voltage converter in accordance with the present invention.

FIG. 12 is a schematic circuit diagram of a fifth embodiment of the voltage converter in accordance with the invention in which the voltage translation circuit is implemented with a logic block.

FIG. 13 is a schematic circuit diagram of the embodiment of FIG. 12 illustrating the logic block thereof in greater detail.

FIG. 14 is a schematic circuit diagram of a voltage translator similar to that of FIG. 13 but providing an output signal having the same polarity as the input signal.

FIG. 15 is a schematic circuit diagram of another voltage translator in accordance with the present invention.

### DETAILED DESCRIPTION OF THE PREFERRED EMBODIMENTS

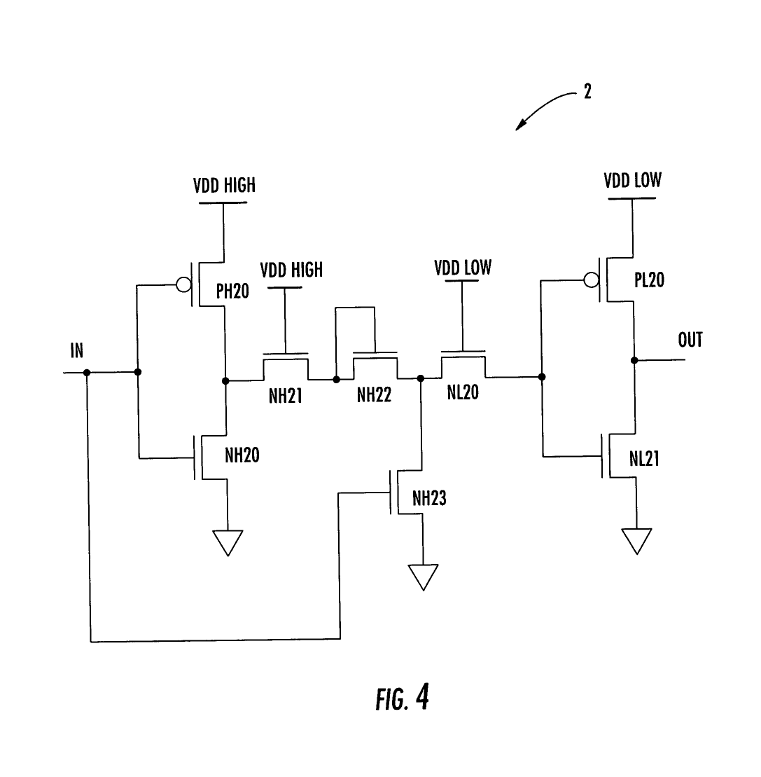

Turning now to FIG. 4, a first embodiment of the voltage translator or converter 2 in accordance with the invention is illustratively shown. The voltage translator 2 includes a high voltage input inverter illustratively including high threshold transistors PH20 and NH20. The first conducting end of transistor PH20 in the high voltage inverter is connected to the high voltage supply V_{DD}_{_{—}}_{HIGH}. The second conducting end of transistor PH20 drives the first conducting end of the transistor NH20, which is also the output of the inverter. The second conducting end of the transistor NH20 is grounded.

The output of the high voltage inverter is connected to a series pass transistor NH21, the control terminal of which is raised to V_{DD}_{_{—}}_{HIGH}. The other conducting terminal of the series pass transistor NH21 is connected to the shorted drain and gate of a second pass transistor NH22. The source of the transistor NH22 is connected to the drains of a low threshold voltage transistor NL20 and a high threshold voltage transistor NH23. The gate of the transistor NH23 is controlled by the input signal, while its source is grounded.

The gate of the transistor NL20 is connected to the lower supply voltage V_{DD}_{_{—}}_{LOW}, while its source is connected to the input of a low voltage inverter including low threshold voltage transistors PL20 and NL21. The source terminals of the transistors PL20 and NL21 are connected to V_{DD}_{_{—}}_{LOW} and ground, respectively. The drains of the transistors PL20 and NL21 are connected together to form the output terminal OUT.

The above-described configuration provides improved performance since the lower threshold transistors are connected to the lower supply voltages only, whereas the higher threshold transistors are supplied by the higher voltage only. Also, the higher voltages are brought down sufficiently before application to the lower threshold transistors, thus producing approximately equal rise and fall delays.

When the input is HIGH, the inverter formed by the transistors PH20 and NH20 outputs a LOW signal that tristates the transistor NH22. When the input is HIGH, the transistor NH23 turns ON and passes the LOW level to the drain of the transistor NL20, which passes it to the gates of the transistors PL20 and NL21. This causes the transistor NL21 to turn OFF while the transistor PL10 is turned ON, thus pulling the OUT terminal to V_{DD}_{_{—}}_{LOW}. In this manner the HIGH input signal at V_{DD}_{_{—}}_{HIGH} is converted to V_{DD}_{_{—}}_{LOW}.

Similarly, when the input is LOW, the transistor NH20 is turned OFF and the transistor PH20 is turned ON. This passes V_{DD}_{_{—}}_{HIGH} to the drain of NH21. The transistor NH21 provides a threshold voltage drop (Vₜₕₙ) and passes a voltage of V_{DD}_{_{—}}_{HIGH}−Vₜₕₙ to the gate and drain of the transistor NH22. This transistor introduces a second threshold voltage drop, bringing the input signal down to V_{DD}_{_{—}}_{HIGH}−2Vₜₕₙ at the drain of the transistor NL20. Since the input is LOW, the transistor NH23 is OFF, allowing the transistor NL20 to pass the voltage V_{DD}_{_{—}}_{LOW}−Vₜₗₙ to the gates of the transistors PL20 and NL21, where Vtln is the threshold voltage of low threshold NMOSs.

Normally, the threshold voltage of PMOS transistors is greater than that of NMOS transistors. Therefore, the transistor PL20 is OFF while the transistor NL21 is ON, thus bringing the output terminal to a LOW logic level. In this manner, the gate-to-source voltage (V_{gs}) and the gate-to-drain voltage (V_{gd}) of the lower threshold transistor are kept smaller than V_{DD}_{_{—}}_{LOW}+Vtln (i.e., by introducing the transistors NH21 and NH22). These transistors drop the high voltage V_{DD}_{_{—}}_{HIGH} by 2Vₜₕₙ before appearing at the transistor NL20 to ensure the safety of the low threshold transistors. Since PMOS transistors threshold voltages are usually greater than NMOS transistors threshold voltage, no crowbar current flows in the circuit.

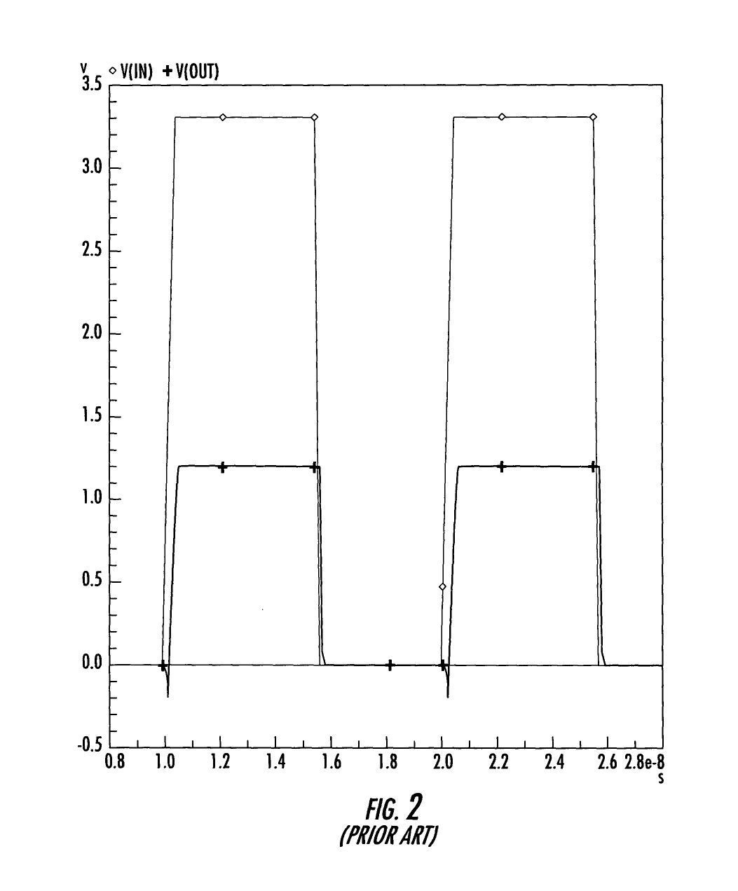

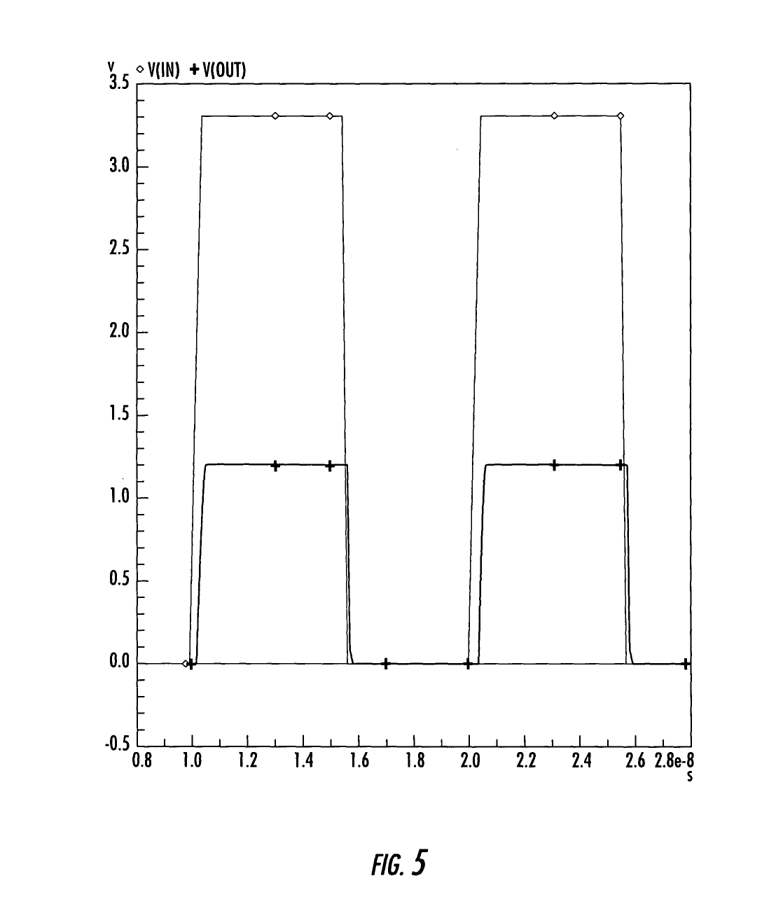

The simulated timing diagram for the voltage translator 2 for V_{DD}_{_{—}}_{HIGH} of 3.3V and V_{DD}_{_{—}}_{LOW} of 1.2V is illustratively shown in FIG. 5. Upon comparing the timing diagram of FIG. 5 with that of FIG. 2 it will be seen that the device of the present invention produces better results than the prior art.

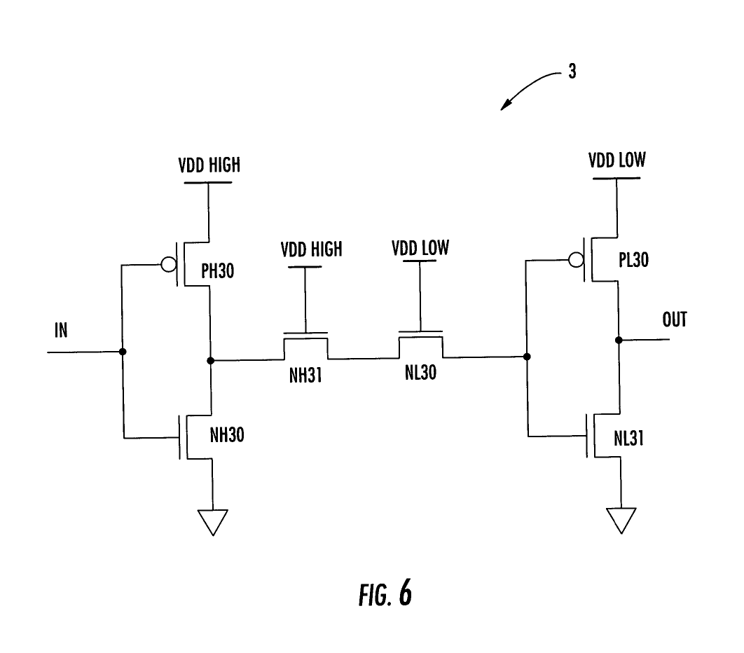

A second embodiment of a voltage translator 3 in accordance with the present invention for the case when V_{DD}_{_{—}}_{HIGH} is 2.5V and V_{DD}_{_{—}}_{LOW} is 1.2V is illustrated in FIG. 6. Here, pass transistors NH22 and NH23 are eliminated, as a single pass transistor NH31 is sufficient to protect the lower threshold transistor NL30. The remaining operation of the circuit is similar to that discussed above for the first embodiment of the invention.

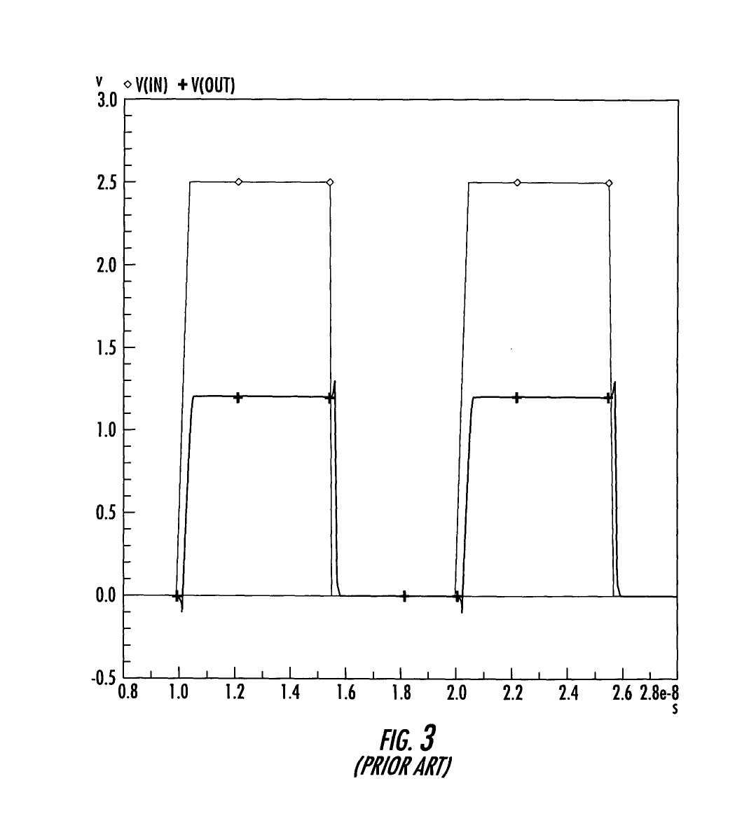

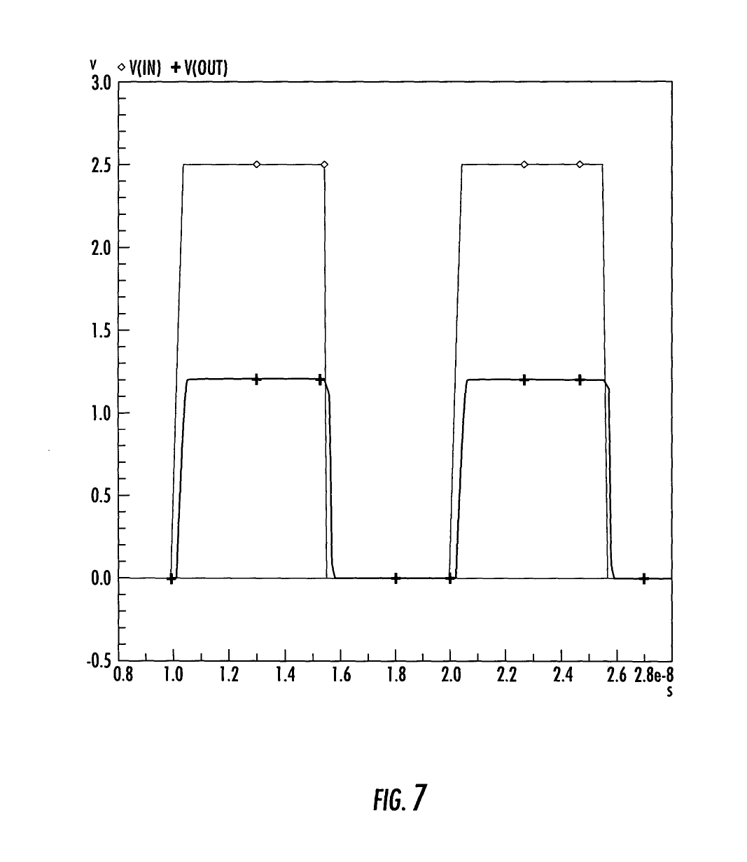

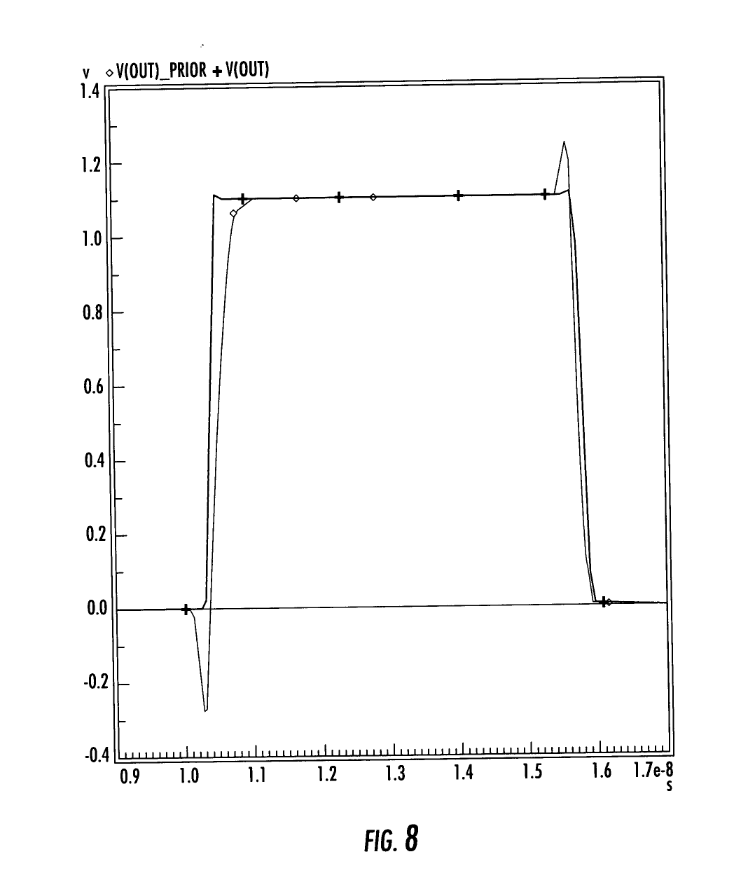

Referring to FIG. 7, the simulated timing diagram for the voltage translator 2 for the V_{DD}_{_{—}}_{HIGH} of 2.5V and V_{DD}_{_{—}}_{LOW} of 1.2V is shown. Again, comparing the timing diagrams of FIG. 8 and FIG. 3 shows that the circuit arrangement of the present invention produces shorter rise and fall delays and rise and fall transition times than the conventional voltage translator of the prior art.

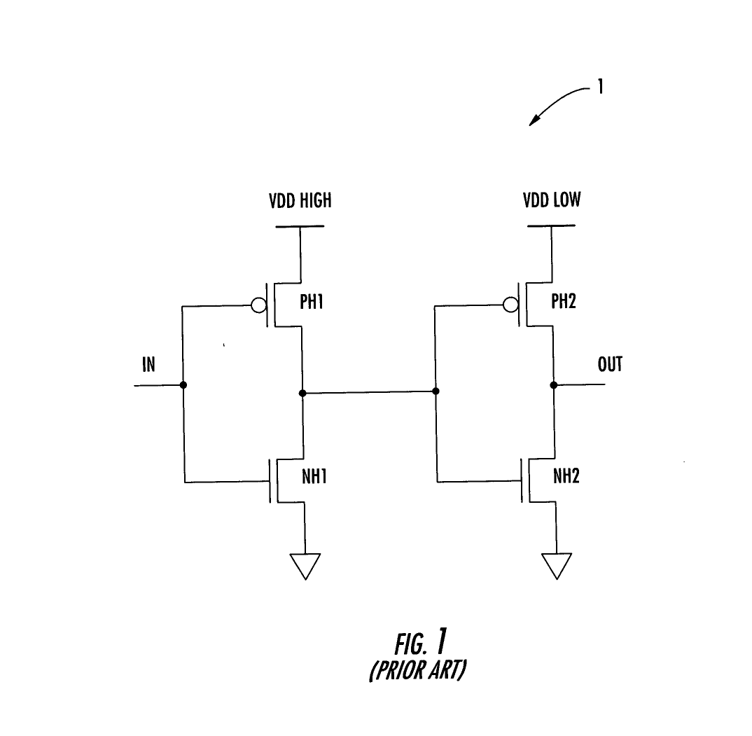

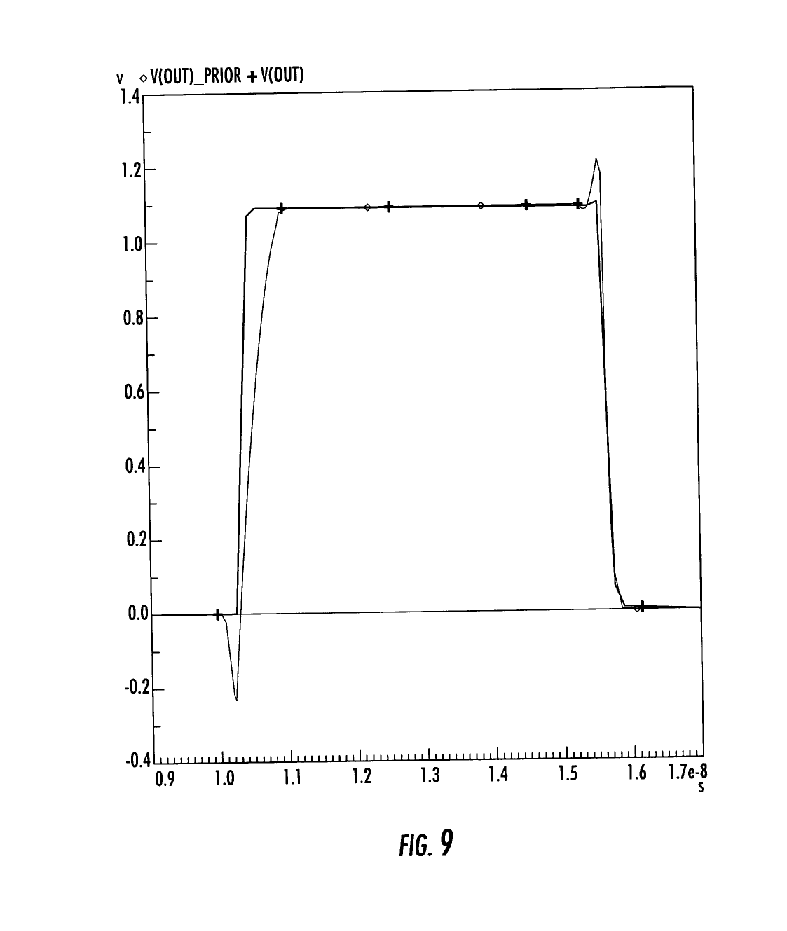

Simulation results for the operation of voltage converts in accordance with the present invention and the prior art where V_{DD}_{_{—}}_{HIGH} is 3.3V and 2.5V and V_{DD}_{_{—}}_{LOW} is 1.2V are illustrated in FIGS. 8 and 9, respectively. Here, VOUT is from the output OUT shown in the illustrated first and second embodiments of the present invention for V_{DD}_{_{—}}_{HIGH} of 3.3V and 2.5V, respectively, whereas V_{OUT}_{_{—}}ₚᵣᵢₒᵣ is the output of the prior art voltage translator 1 of FIG. 1. The simulated results are for a worst-worst case, i.e., when temperature, supply voltage, and/or process parameters are at their worst or slowest. From the illustrated comparison it will be appreciated that the present invention returns better results than those of the prior art device.

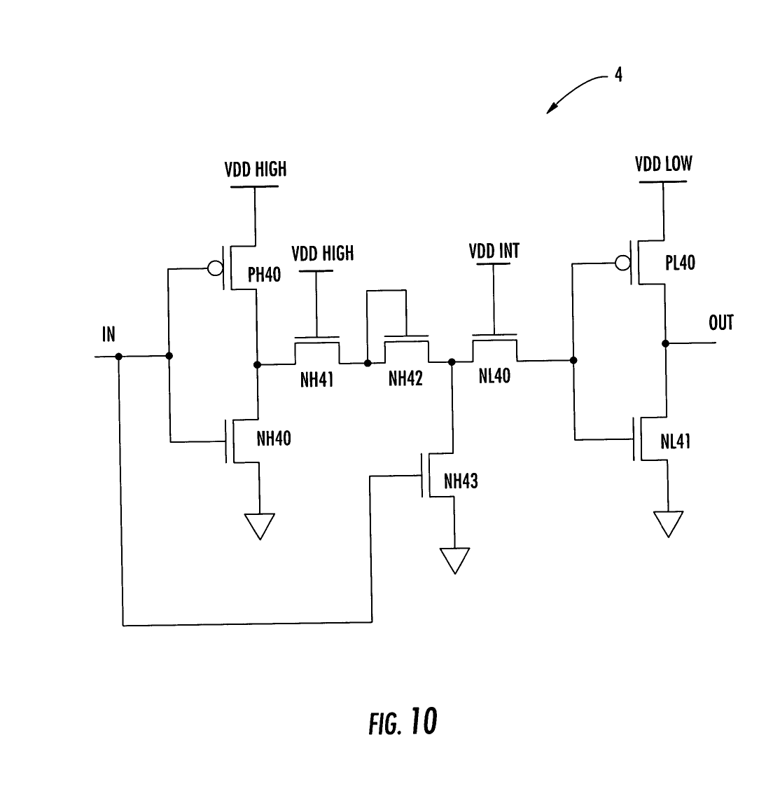

A third embodiment 4 of the invention is illustratively shown in FIG. 10. In this example, an intermediate voltage V_{DDINT} is introduced at the control terminal of a pass transistor NH40. For translating 3.3V to 1.2V, the intermediate voltage V_{DDINT} is selected as 1.8V, whereas for a 5V to 2.5V conversion V_{DDINT} may be 3.3V, for example. The use of V_{DDINT} again reduces the likelihood of a crowbar current in the circuit.

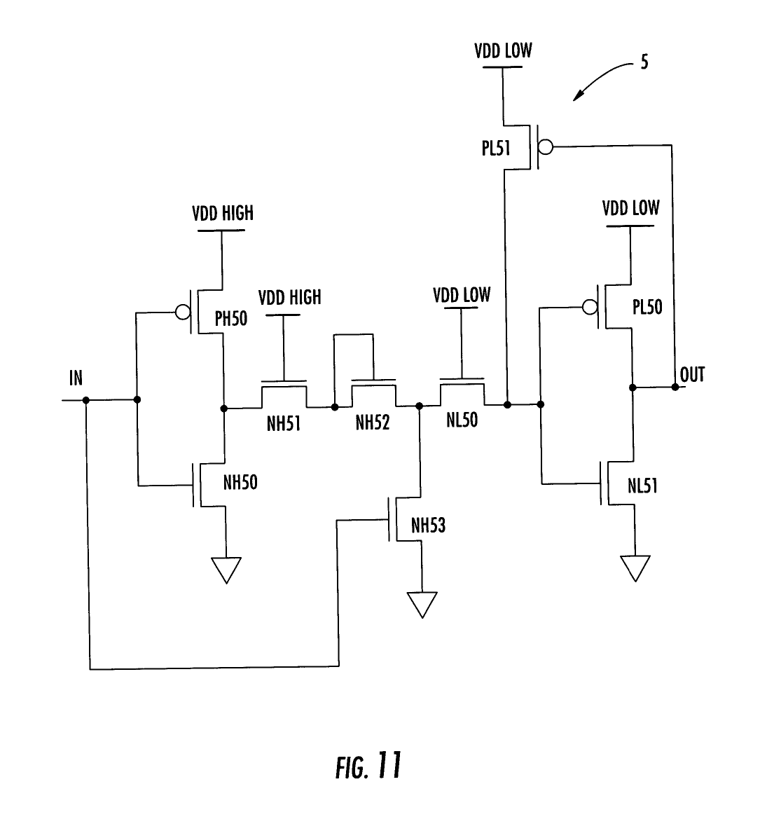

Referring to FIG. 11, a fourth voltage translator embodiment 5 in accordance with the invention is illustratively shown. In this embodiment, feedback is taken from the output through PL51 so that transistors PL50, PL51 and PL50 form a half latch. This half latch is used to restore the HIGH logic level and V_{DD}_{_{—}}_{LOW} at the gates of the transistors PL50 and NL50. This approach again reduces the possibility of a crowbar current in the circuit.

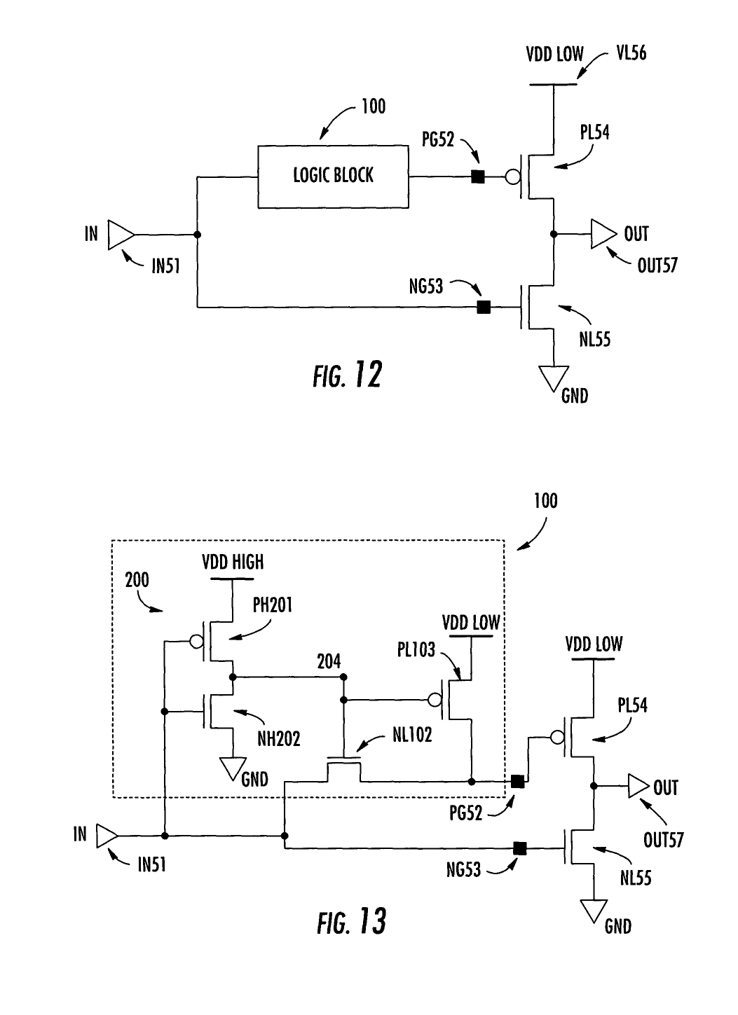

Yet another implementation of a voltage translator in accordance with the invention is shown in FIG. 12. The signal IN at the terminal IN51 has to swing from 0V to a high voltage level of VDD HIGH (e.g., 3.3V). The terminal IN51 is directly connected to the gate NG53 of NMOS transistor NL55. The source of NMOS transistor NL55 is connected to ground GND, and the drain is connected to a terminal OUT57. The terminal OUT57 is the low voltage output of the circuit for loads operating at the lower voltage VDD LOW (e.g., 1.2V) providing a voltage swing at the terminal OUT57 from 0V to 1.2V.

Since the NMOS transistor NL55 has an input swing of 3.3V, it preferably uses 3.3V device NMOS transistors having a higher gate length and thicker gate oxide to be compatible with 3.3V operation. The transistor NL55 provides desired performance for Vgs=3.3V. When the signal at the input terminal IN51 is at logic 0, it provides a voltage of 0V which turns off the transistor NL55. When the signal at the terminal IN51 is at logic 1, it provides a voltage of 3.3V at the gate NG53 of the transistor NL55, which turns it on. When the transistor NL55 is on, its Vgs=3.3V. This enables good sinking capability and provides a rapid falling edge of the signal at the terminal OUT57.

A PMOS transistor PL54 has its drain connected to the terminal OUT57, while its source is connected to power supply VDD LOW, which is 1.2V. Its gate is coupled to a node PG52, which is the output of the logic block 100. Since the source voltage of the PMOS transistor PL54 is only at 1.2V, the PMOS transistor PL54 is preferably a 1.2V device to provide desired rise-time performance. That is, this device preferably has a shorter gate length and thinner gate oxide compared to that of 3.3V-rated transistors. Also, the voltage swing at the gate of the transistor PL54 is preferably limited to 1.2V to prevent oxide break down.

The logic circuit 100 connected between the terminal IN51 and the node PG52 accomplishes the foregoing by taking the input from the terminal IN51 with a voltage swing of 0V to 3.3V and providing an output at the node PG52 with a voltage swing of 0V to 1.2V. The output of the logic block 100 is non-inverting. A 0V input generates a 0V output, while a 3.3V at the terminal IN51 generates a 1.2V output at the node PG52. The functioning of logic block 100 is such that it allows a 0V input to pass through itself, but when the signal at the terminal IN51 rises above 0V the output at the node PG52 follows the input signal until it reaches 1.2V, after which the voltage level saturates.

The logic block 100 maintains the output at the node PG52 at 1.2V until the signal at the terminal IN51 starts decreasing from 3.3V and reaches 1.2V, after which the output at the node PG52 again follows the terminal IN51 down to 0V. In this manner the voltage swing of 0V to 3.3V at the terminal IN51 is translated to 0V to 1.2V swing at the node PG52 by the logic block 100.

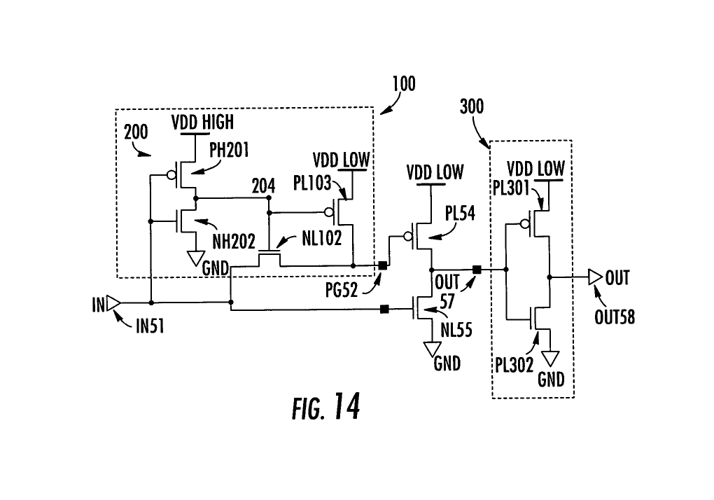

One advantageous embodiment of the logic block 100 is illustratively shown in FIG. 13. The logic block 100 includes an inverter 200 having an NMOS transistor NH202 and a PMOS transistor PH201. The gate of the NMOS transistor NH202 is connected to the input terminal IN51. Further, its drain is connected to the node 204, and its source is connected to ground. The gate of the PMOS transistor PH201 is also connected to the input terminal IN51, while its drain is connected to the node 204 and its source is connected to the higher supply voltage VDD HIGH.

Since the inverter 200 experiences an input swing from 0V to VDD HIGH and operates from the higher power supply VDD, higher voltage devices are preferably used for the NMOS transistor NH202 and PMOS transistor PH201. The gate of the NMOS transistor NL102 is connected to the node 204, while its drain is connected to the node PG52 and its source is connected to the input terminal IN51. Since the swing at the source and gate of the NMOS transistor NL102 is from 0 to the higher voltage level VDD HIGH it is preferably a high voltage device. The gate of the PMOS transistor PL103 is connected to the node 204, while its drain is connected to the node PG52 and its source is connected to the lower voltage level VDD LOW. Since the voltage swing at the gate of the transistor PL103 is from 0 to the higher voltage level VDD HIGH, it is preferably a high voltage device.

When the signal at the input terminal IN51 is at 0V, the gate of NMOS transistor NL55 is at 0V, causing it to turn off. This produces a VDD HIGH level at the node 204 of the inverter 200. VDD HIGH at the node 204 turns NMOS transistor NL102 on and turns off PMOS transistor PL103. Since the NMOS transistor NL102 is on, it passes 0V from input terminal IN51 to its output at the node PG52, causing the PMOS transistor PL54 to turn on. This provides a signal of VDD LOW at the terminal OUT57.

When the signal at the input terminal IN51 starts increasing from 0V, the gate voltage of the NMOS transistor NL55 follows the terminal IN51. The width of the transistors PH201 and NH202 are selected to adjust the trip point of the inverter 200 to a level equal to VDD LOW. Therefore, as the signal at the terminal IN51 reaches VDD LOW, it trips the inverter 200, causing 0V to appear at the node 204. A value of 0V at the output node 204 turns off the NMOS transistor NL102 and isolates the node PG52 from the terminal IN51. This stops further propagation of the signal from the terminal IN51 to the node PG52. Also, 0V at the node 204 turns on the PMOS transistor PL103, thus connecting the node PG52 to the VDD LOW supply voltage.

The presence of the VDD LOW voltage at the node PG52 turns off the PMOS transistor PL54. When the voltage at the terminal IN51 increases from 0V to a value equal to the threshold voltage of the NMOS transistor NL55, it turns on the transistor and applies 0V at the terminal OUT57. In this manner the input swing of 0V to VDD HIGH at the terminal IN51 is converted to a voltage swing of 0V to VDD LOW at the terminal OUT57, but with a polarity opposite to the polarity of the input of the circuit. Since the load for the logic block 100 is limited to the small gate capacitance of the PMOS transistor PL54, the required size for the NMOS transistor NL102 is small. Further, the slew rate at the node PG52 is approximately the same as at terminal IN51.

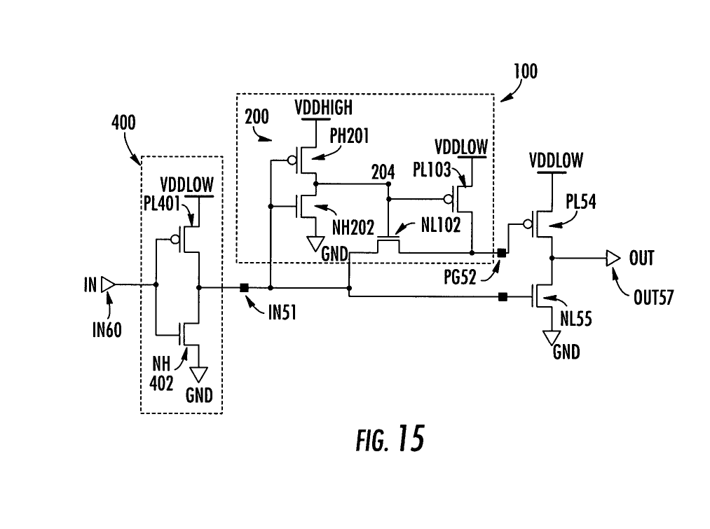

Referring now to FIG. 14, a voltage translator with an output signal having the same polarity as that of the input signal is illustratively shown. To achieve the same polarity an inverter 300 is connected at the output terminal OUT57. A PMOS transistor PL301 of the inverter 300 has its gate connected to the output terminal OUT57, its drain connected to the terminal OUT58, and its source connected to the VDD LOW supply. Since the input swing for the PMOS transistor PL301 is 0 to VDD HIGH, and its supply voltage is VDD LOW, it is preferably a VDD LOW device.

The NMOS transistor NL302 of the inverter 300 has its gate connected to the terminal OUT57, its drain is connected to the terminal OUT58, and its source is connected to ground. The input swing for the NMOS transistor NL302 is from 0V to VDD LOW and the voltage which appears at its input is VDD LOW, thus it is preferably a VDD LOW device.

The sizes of the PMOS transistor PL301 and NMOS transistor NL302 are adjusted according to the load at the terminal OUT58, to get the required slew rates at terminal OUT58 and to get better delays. In this manner the desired driving capability is achieved by increasing the driving capability of the inverter 300. In addition, by sizing the width of the NMOS transistor NL302 and PMOS transistor PL301, the rise delays and fall delays can be made equal and the slew rates can be adjusted as required. Since its load is limited to that of the inverter 300, the size of the PMOS transistor PL54 can be as low as 1/2.5 times the size of the inverter 300. This reduces the loading for the signal at the terminal IN51 and for the NMOS transistor NL102, which thus reduces the propagation delay.

An embodiment of a complete voltage translator with the output signal at the terminal OUT57 having the same polarity as the input signal at the terminal IN60 is illustratively shown in FIG. 15. In this circuit an inverter 400 is connected before the terminal IN51. A PMOS transistor PH401 of the inverter 400 has its gate connected to the input terminal IN60, while its drain is connected to the terminal IN51 and its source is connected to the VDD HIGH power supply. An NMOS transistor NH402 has its gate connected to the input terminal IN60, while its drain is connected to the terminal IN51 and its source is connected to ground. Since both the NMOS and PMOS transistors have an input signal swing of VDD HIGH at their gates and operate off a VDD HIGH power supply, both are preferably VDD HIGH devices.

It will be apparent to those skilled in the art that the foregoing embodiments are merely illustrative of the present invention, and are not intended to be exhaustive or limiting. These embodiments have been presented by way of example only, and various modifications may be made within the scope of the above invention. For instance, the number of series-connected transistors may be varied. Similarly, the intermediate voltage levels may be different from those described above. Such changes and modifications are understood to be included within the scope of the present invention as set forth in the following claims.

That which is claimed is:

1. A digital electronic circuit providing high-level to low-level voltage translation with equal rise and fall delays and equal rise and fall transition times, comprising:
an input high-voltage logic inverter operating at the high-level voltage,
an output low-voltage logic inverter operating at the low-voltage level, and
a voltage translation means coupling the output of the high-voltage inverter to the input of the low-voltage inverter.

2. A digital electronic circuit as claimed in claim 1 wherein the voltage translation means is a digital electronic circuit comprising a plurality of series-connected transistors each of which is biased to provide a fixed voltage drop.

3. A digital electronic circuit as claimed in claim 2 wherein the voltage translation means provides a voltage that is not less than one threshold voltage below the low voltage level in the high state while ensuring that it never exceeds the maximum voltage rating of the low voltage transistors, so as to minimize output inverters leakage current and avoid the possibility of crowbar conduction or transistor breakdown.

4. A digital electronic circuit as claimed in claim 2 wherein the voltage translation means includes an additional transistor connected to feedback the output of the low-level inverter to its input to minimize output leakage current and avoid the possibility of crowbar conduction.

5. A digital electronic circuit as claimed in claim 1 wherein the voltag translation circuit is a logic block that provides an output that follows the input until the low-voltage supply voltage iss reached and thereafter maintains the output at the supply voltage level while the input continues rising.

6. A digital electronic circuit as claimed in claim 5 wherein the logic block comprises a low-voltage transistor having its common terminal connected to the low-voltage supply while its output terminal is connected to, the output terminal of a transistor having its control terminal connected to the input of the voltage limiting circuit, while its common terminal provides the complementary output from the voltage limiting cirucit.

7. A method for translating a high-level voltage to a low-level voltage while providing equal rise and fall delays and equal rise and fall transition times comprising the steps of:
providing a high-voltage input inverter operating at the high-level voltage,
providing at the low-level voltage, and
coupling the output of the high voltage input inverter to the input of the low-voltage output inverter after degrading it to the required level.

8. A method as claimed in claim 7 wherein the degrading of the voltage level from the output of the high-voltage inputinverter is performed by passing it through a plurality of transistors connected in series with each transistor being biased to provide a fixed voltage drug.

9. A method as claimed in claim 7 wherein the degraded voltage is adjusted to provide a voltage level that is greater than one threshold voltage below the low voltage level in the high state while ensuring that it never exceeds the maximum voltage rating of the low voltage transistors, so as to minimize output inverter leakage currect and avoid the possibility of crowbar conduction or transistor breakdown.

10. A method as claimed in claim 7 inlcuding providing feedback from the output of the output inverter to its input when the output is in the high state, so as to minimize output inverter leakage and avoid the possibility of crowbar conduction.

11. A method as claimed in claim 7 comprising the steps of:
limiting the output from the high-voltage digital inverter to the desired lower voltage levels; and
using the limited voltage swing to drive an output low-voltage digital inverter.

12. A method as claimed in claim 11 wherein the output from the high-voltage digital inverter is converted to the desired low voltage levels by voltage limiting it to the levels of the low voltage supply.
